(19) United States
(12) Patent Application Publication
(10) Pub. No.: US 2013/0023196 A1
(43) Pub. Date: Jan. 24, 2013

(54) UNIQUE DOAS SYSTEM DESIGNED FOR INTEGRATION WITH RECIRCULATION AIR HANDLING SYSTEMS

(71) Applicants: Mark Thomas FISHER, Reston, VA (US); Bryan Keith DUNNAVANT, Lexington, VA (US)

(72) Inventors: Mark Thomas FISHER, Reston, VA (US); Bryan Keith DUNNAVANT, Lexington, VA (US)

(73) Assignee: MUNTERS CORPORATION, Selma, TX (US)

(21) Appl. No.: 13/555,917

(22) Filed: Jul. 23, 2012

Related U.S. Application Data
(60) Provisional application No. 61/510,830, filed on Jul. 22, 2011.

(51) Int. Cl. F24F 7/00; B01D 50/00; H05K 5/02; B01D 46/00; F25B 1/00; F24F 13/10

(52) U.S. Cl. 454/254; 62/498; 454/333; 454/184; 55/385.2; 95/273; 95/39

(57) ABSTRACT

An integrated air handling system having a make-up air system that treats outside air and a recirculating system that mixes the treated outside air with building return air. The make-up air system may include a filter, a dehumidifier, a humidifier, a combination of a dehumidifier and a humidifier, and/or an exhaust fan. The mixed air is supplied to a structure.

This nonprovisional application claims the benefit of U.S. Provisional Application No. 61/510,830, filed Jul. 22, 2011.

### BACKGROUND

This disclosure is directed to systems and methods to integrate a make-up air Dedicated Outdoor Air System with recirculation air handling systems, for example, to provide air to a data center, in an efficient and effective manner.

Make-up air is generally required in commercial spaces to satisfy codes and provide positive pressurization so as to reduce unwanted infiltration of unconditioned outdoor air. Make-up air is generally introduced by a machine separate from a recirculation air handler. This make-up air may be introduced by a Dedicated Outdoor Air System (DOAS), which processes the outdoor air prior to its entering a building. The DOAS processing often includes humidifying, dehumidifying, cooling and heating.

A typical make-up air system, with a Humidification or a Dehumidification/Humidification Unit, is known and disclosed in U.S. patent application Ser. No. 12/929,002.

The typical approach of introducing make-up air at a separate location from the system carries inherent disadvantages with regards to efficiency and effectiveness. There is a need, especially in cases where buildings have large recirculating air handling systems, for example, in a data center, to integrate the make-up air system with a recirculating air handling system to improve efficiency and reduce costs.

### SUMMARY

Disclosed herein is a DOAS system that provides controlled ventilation introduction integrated into a recirculation air handling system. The system may include a make-up air module that has the ability to, for example, filter ventilation air, dehumidify and humidify, as needed to, for example, control building pressure and dew point.

This integration allows for a complete and efficient method and apparatus for introducing and conditioning the required amount of make-up air. The effects of the integration may include optimal energy efficiency, improved ventilation effectiveness, ease of control, reduced installation costs, and smaller overall apparatus footprint.

### BRIEF DESCRIPTION OF THE DRAWINGS

FIG. 1 shows an embodiment of an integrated system that includes integrating a make-up air system with a recirculating air system.

FIG. 2 shows an embodiment of an integrated system that additionally includes a dehumidification coil for humidity control within the make-up air system.

FIG. 3 shows an embodiment of a portion of an integrated system that includes a humidification section within the recirculation air system.

FIG. 4 shows an embodiment of an integrated system that includes both a recirculation air humidification section and a make-up air system with dehumidification coil.

FIG. 5 shows an embodiment of an integrated system that includes a make-up air system with dehumidification coil and a recirculation air humidification section, that by implementation of isolation dampers further functions as an outdoor evaporatively cooled condenser for rejecting the heat of compression from the make-up air dehumidification process.

### DETAILED DESCRIPTION OF THE EMBODIMENTS

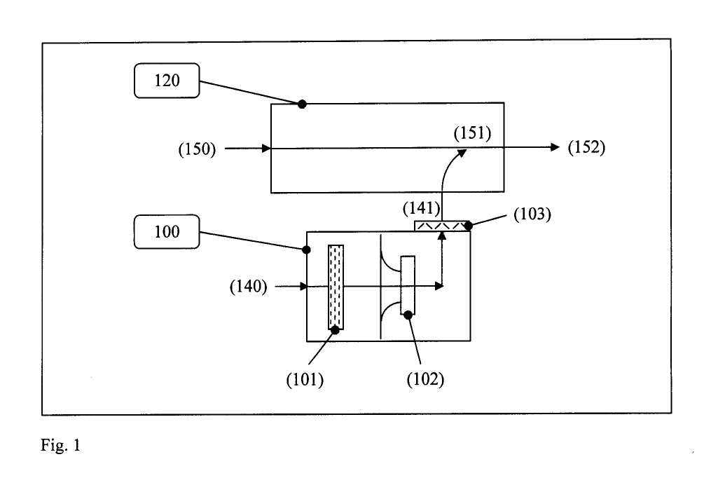

Referring to FIG. 1, which shows integrating make-up air into a recirculating air system, the outside air stream 140 enters the make-up air system. The outside air stream 140 may be processed through at least one make-up air filter 101 and through a make-up air supply fan 102. The make-up air supply fan 102 regulates airflow through the make-up air system 100. The make-up air supply fan 102 may be any type of fan, including plenum or scroll fans.

The treated make-up air then may pass through an isolation damper (i.e., make-up air shutoff control) 103 and exits the make-up air system as treated make-up air (i.e., make-up system supply air) 141. The isolation damper 103 may, for example, open when the ventilation function is operable and close as necessary to isolate the recirculating air system 120 from the ventilation air system for servicing or other reasons

The treated make-up air 141 then mixes with the building recirculating air 150 upon entering the recirculating air system 120. The combination of air has thus been adequately filtered to comply with relevant standards and the ventilation air delivered is intended to reduce unwanted infiltration into the building.

The mixed air 151 is a combination of the treated make-up air 141 and the building recirculating air 150. The make-up air volume is established by codes and as required to ensure proper indoor air quality and building pressurization.

The mixed air 151 is then processed through the remainder of the recirculating air system 120 and enters the building as building supply air stream 152.

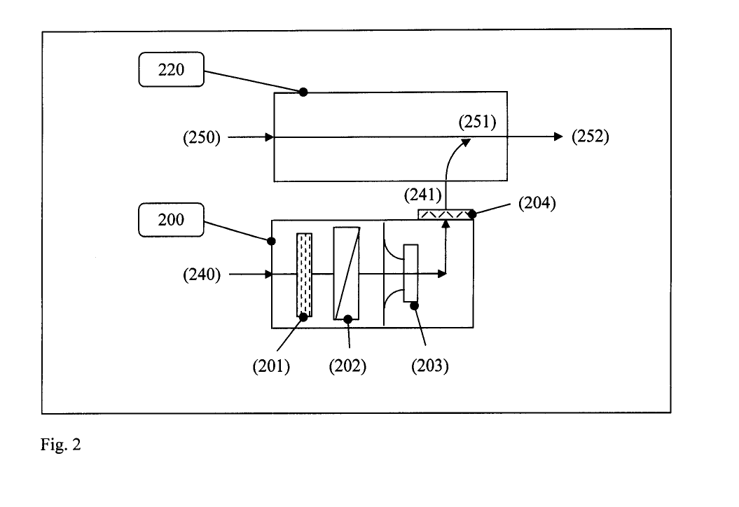

Referring to the embodiment shown in FIG. 2, where make-up air is integrated into a recirculation air system, the outside air stream 240 enters the make-up air system with dehumidification 200. The outside air stream 240 may be processed through at least one make-up air filter 201.

Next, the outside air 240 may dehumidified by dehumidification device 202. The dehumidification process may occur, for example, during humid ambient conditions as required to control the humidity of the building. The dehumidification process may occur when the dew point of the outdoor air is, for example, above 59° F. The dehumidification process may continue until the dew point of the outdoor air is, for example, less than the upper limit of ASHRAE recommended supply air dew point of 59° F.

Any dehumidification device known in the art may be used as dehumidification device 202, including, for example, a refrigeration or chilled water coil, or a desiccant wheel.

Dehumidifying the outside air 240 may have the advantages of, for example, reducing the risk of mold and increasing comfort of those in the building, or reducing the risk of certain types of circuit board corrosion that might otherwise result from high humidity.

Next, the dehumidified outside air 240 may be processed through make-up air supply fan 203. The make-up air then passes through an isolation damper (i.e., make-up air shutoff control) 203 and exits the make-up air system as treated air (i.e., make-up system supply air) 241.

The treated make-up air then mixes with building recirculating air 250 upon entering the recirculating air system 220.

The mixed air 251 is a combination of the treated make-up air 241 and the building return air 250.

The mixed air 251, which has been sufficiently dehumidified by virtue of the outside air 240 passing through the dehumidification device 203 of the make-up air system 200, may then be processed through the remainder of the recirculating air system 210 and enters the building as building supply air stream 252.

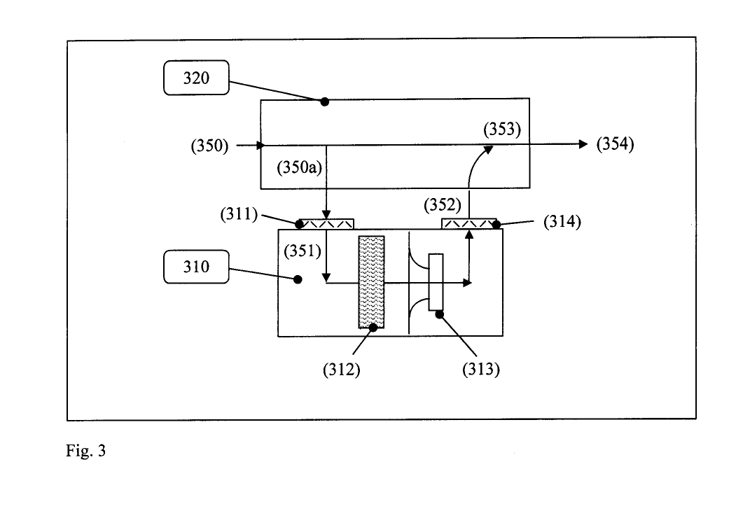

Referring to the embodiment shown in FIG. 3, which includes a recirculation air side-stream humidification system 310, which may be the humidification portion of a make-up air system, and the recirculating air system 320, the side-stream air humidification system 310 may include a direct evaporative cooler (DEC) 312, also known as an adiabatic type humidifier, and a humidification supply air fan 313.

The DEC 312 may be any type of direct evaporative cooler known in the art, for example, an evaporative media pad.

Humidification may be accomplished by taking a separate side-stream of return air 350a from the building return air (recirculated air stream) 350 of a recirculating air system 320. This side-stream of return air 350a may be passed through an isolation damper (i.e., humidification system intake shut-off control) 311 as humidification system intake air stream 351, and then through DEC 312, which cools and humidifies the humidification system intake air stream 351. The humidification system intake air stream 351 may then be passed through a humidification system supply air fan 313 and then passed through an isolation damper (i.e., humidification system supply shut-off control) 314. The resultant humidification system supply air stream 352 may then enter back into the recirculating air system 320. The net result of the humidification process is humidification and cooling without need for pre-heat or steam. A further benefit of wet pad type humidification is that it does not require special water treatment such as Reverse Osmosis or DI as is often required for other forms of humidification.

The side-stream air 350a may be warm, relatively dry air. An appropriate amount of moisture may be added to the recirculated air stream to satisfy, for example, the humidification requirements of the make-up air or building space or return air.

The humidification system supply air stream 352 may then mix in an appropriate ratio with the building return air 350 upon entering the recirculating air system. The mixed air 351 is a combination of the humidification system supply air stream 352 and the building return air 350. The ratio of humidification system air to make-up air volume may be any required ratio, for example, between 2:1 and 4:1. The mixed air 353 is then processed through the remainder of the recirculating air system and enters the building as building supply air 354.

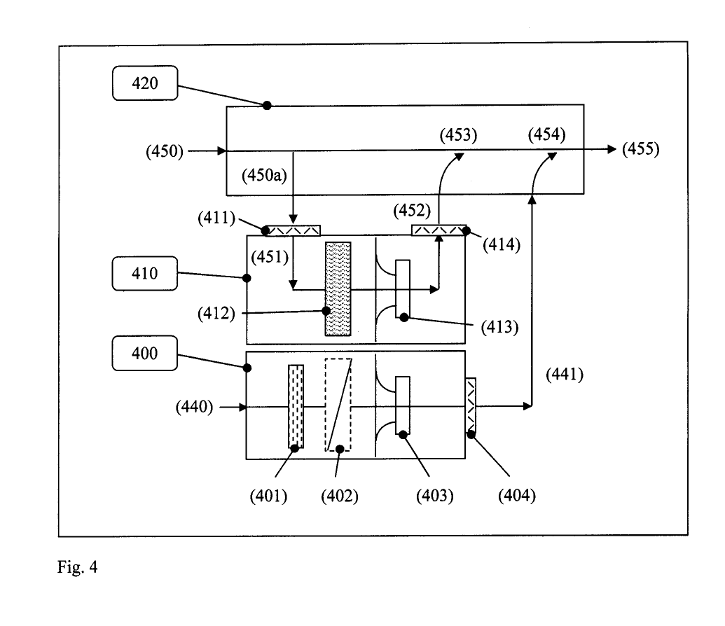

Referring to the embodiment shown in FIG. 4, the make-up air system 400 with dehumidification and humidification system 410 are shown. The humidification system 410 may be considered part of, or in addition to, the make-up air system.

In FIG. 4, outside air 440 enters the make-up air system 400 and building return air (recirculating air stream) 450 enters the recirculating air system 420. The outside air 440 may be processed through at least one make-up air filter 401 and then through dehumidification device 402, so as to be adequately dehumidified, if necessary. The outside air 440 may then be processed through a make-up air fan 403 before leaving the make-up air system through an isolation damper (make-up air shut-off) 404. The dehumidification process may occur, for example, during humid ambient conditions as required to control the humidity of the building. The dehumidification process may occur when the dew point of the outdoor air is, for example, above 59° F.

Any dehumidification device known in the art may be used as dehumidification device 404, including, for example, a chilled water or refrigeration coil, or a desiccant wheel.

The filtered air may exit the isolation damper 404 and continue as a make-up system supply air stream 441.

Additionally, in the side-stream humidification portion 410, which may also be considered part of, or alternatively in addition to, the make-up air system, humidification may be accomplished by taking a separate side-stream of return air 450a from the building return air (recirculated air stream) 450 of a recirculating air system 420. This side-stream of return air 450a may be passed through an isolation damper (i.e., humidification system intake shut-off control) 411 as humidification system intake air stream 451, and then through DEC 412, which cools and humidifies the humidification system intake air stream 451. The humidification system intake air stream 451 may then be passed through a humidification system supply air fan 413 and then passed through an isolation damper (i.e., humidification system supply shut-off control) 414. The resultant humidification system supply air stream 452 may then enter back into the recirculating air system 420. The net result of the humidification process is humidification and cooling without need for pre-heat or steam.

The humidification system supply air stream 452 may then mix in an appropriate ratio with the building return air 450 upon entering the recirculating air system. The mixed air 453 is a combination of the humidification system supply air stream 452 and the building return air 450. The mixed air 453 is then processed through the remainder of the recirculating air system.

Treated make-up air (from the make-up system supply air stream) 441 may then be mixed in an appropriate amount with the mixed air 453 or otherwise with recirculating air stream 450 upon entering the recirculating air system 420. The combination of air has thus been adequately treated to comply with building codes, control building humidity, and to provide the necessary ventilation for proper indoor air quality and to reduce unwanted infiltration into the building.

The resultant make-up mixed air 454 is at least a combination of the treated make-up air and the building return air.

The make-up mixed air 454 may then be processed through the remainder of the recirculating air system 420 and enter the building as building supply air 455.

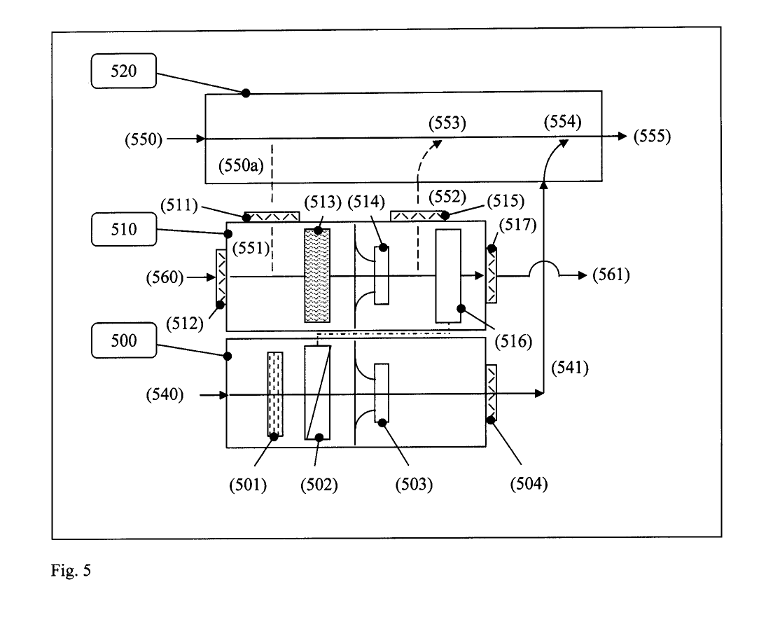

Referring to the embodiment shown in FIG. 5, the make-up air system 500 with dehumidification and humidification system 510 are shown. The humidification system 510 may be considered part of, or in addition to, the make-up air system.

When both a humidification system 510 and a dehumidification make-up air system 500 are included, it may be advantageous to integrate within the humidification system an evaporatively-cooled condensing section for use with refrigeration-based dehumidification systems. During times when dehumidification is required, for example, when the dew point of the outside air (the make-up system intake) 540 is greater than 59° F. This may be accomplished by isolating the humidification loop from the recirculating system 510 entirely, and instead allowing ambient air to be drawn through, using DEC 513 to create the evaporative cooling effect, and then exhausting cooled ambient air through a condenser coil 516, where the heat of compression from the dehumidification system is rejected.

Thus, in FIG. 5, outside air 540 may be processed through make-up air filters 501. Next, the outside air 540 may be processed through dehumidification system 502, so as to be adequately dehumidified. The outside air 540 may then be processed through make-up air supply fan 503 and passed through isolation damper (i.e., make-up air shutoff control) 504. The make-up air then leaves the make-up air system as make-up system supply air stream 541.

Make-up system supply air 541 may then be mixed with building return air 550 to form mixed air 554.

The mixed air 554 may then be processed through the remainder of the recirculating air system 520 and enter the building as building supply air stream 555.

During make-up air dehumidification, outside air 560 may also enter the humidification system 510 through isolation damper (condenser system outside air shut-off) 512. Outside air 560 may then pass through DEC 513 and may be evaporatively cooled. Outside air 560 may then pass through at least one humidification system supply air fan 514. The air may then be exhausted through a condenser coil 516. Exhausted air 561 then may exit the system through isolation damper (condenser system exhaust shut-off) 517 without entering the recirculating system.

Additionally, in the side-stream humidification portion 510, which may also be considered part of, or alternatively in addition to, the make-up air system, humidification may be accomplished by taking a separate side-stream of return air 550a from the building return air (recirculated air stream) 550 of a recirculating air system 520. This side-stream of return air 550a may be passed through an isolation damper (i.e., humidification system intake shut-off control) 511 as humidification system intake air stream 551, and then through DEC 513, which cools and humidifies the humidification system intake air stream 551. The humidification system intake air stream 551 may then be passed through a humidification system supply air fan 514 and then passed through an isolation damper (i.e., humidification system supply shut-off control) 515. The resultant humidification system supply airstream 552 may then enter back into the recirculating air system 520. The net result of the humidification process is humidification and cooling without need for pre-heat or steam.

The humidification system supply air stream 552 may then mix with the building return air 550 upon entering the recirculating air system. The mixed air 553 is a combination of the humidification system supply air stream 552 and the building return air 550. The mixed air 553 is then processed through the remainder of the recirculating air system. Note that humidification and dehumidification are independent processes that never occur at the same time.

The make-up air system 500 may be controlled by a larger air-handling unit control system, or by a separate controller. The make-up air system 500 may receive power from the main air handling unit control feed, a dedicated power feed, or another power feed.

The make-up air system filters 501 may optionally include, for example, a pre-filter and a final filter. The pre-filter may, for example, be about 2 inches deep and have a minimum efficiency reporting value (MERV) of 8.

The final filter may be, for example, about 4 inches deep. The final filter may have, for example, a MERV rating of 11, 13 or higher.

Finally, it should be noted that the above-mentioned embodiments illustrate rather than limit the invention, and that those skilled in the art will be capable of designing many alternative embodiments without departing from the scope of the invention as defined by the appended claims. In the claims, any reference signs placed in parentheses shall not be construed as limiting the claims. The word “comprising” and “comprises,” and the like, does not exclude the presence of elements or steps other than those listed in any claim or the specification as a whole. The singular reference of an element does not exclude the plural reference of such elements and vice-versa. In a device claim enumerating several means, several of these means may be embodied by one and the same item of software or hardware. The mere fact that certain measures are recited in mutually different dependent claims does not indicate that a combination of these measures cannot be used to advantage.

What is claimed is:

1. An integrated air handling system comprising:
a make-up air system that treats a first air stream; and
a recirculating air system that mixes the treated first air stream and a building return air stream into a mixed air stream and supplies the mixed air stream to a structure.

2. The integrated air handling system according to claim 1, where in the make-up air system comprises a filter that filters the first air stream.

3. The integrated air handling system according to claim 1, wherein the make-up air system comprises a dehumidifier that dehumidifies the first air stream.

4. The integrated air handling system according to claim 1, wherein the make-up air system comprises a humidifier that humidifies the first air stream indirectly by humidification of a recirculation air side stream.

5. The integrated air handling system according to claim 1, wherein the make-up air system comprises a pre-filter and a final filter.

6. The integrated air handling system according to claim 3, wherein the dehumidifier dehumidifies the first air stream to a dew point that is sufficiently low so as to ensure that the return air is of a dew point not greater than 59° F.

7. The integrated air handling system according to claim 3, wherein the humidifier humidifies an appropriate volume flow of recirculation air to a dew point level such that the return air has a dew point that is not less than 41.9° F.

8. The integrated air handling system according to claim 1, wherein the make-up air system further comprises:
at least one compressor;
at least one evaporator coil; and
at least one condenser coil.

9. The integrated air handling system according to claim 1, further comprising at least two isolation dampers.

10. The integrated air handling system according to claim 1, wherein the structure includes a data center.

11. A method for integrating a make-up air system with a recirculating air system, comprising:
introducing a first air stream into a make-up air system;
treating the first air stream in the make-up air system;
injecting the treated first air-stream into the recirculating air system;
mixing the treated first air stream with a building return air stream; and
supplying the mixed air stream to a structure.

12. The method of claim 11, wherein the make-up air system includes a filter.

13. The method of claim 11, wherein the make-up air system includes a dehumidifier.

14. The method of claim 11, wherein the make-up air system includes a humidifier.
